(19) United States
(12) Patent Application Publication
(10) Pub. No.: US 2026/0348742 A1
(43) Pub. Date: Nov. 5, 2026

(54) TOGGLE CONTROL DEVICE

(71) Applicant: TIMOTION TECHNOLOGY CO., LTD., New Taipei City (TW)

(72) Inventor: Yu-Chang LIN, New Taipei City (TW)

(21) Appl. No.: 19/319,642

(22) Filed: Sep. 4, 2025

(30) Foreign Application Priority Data
May 5, 2025 (TW) 114116804

(51) Int. Cl. G01D 5/14; A47B 21/02; H03K 17/97

(52) U.S. Cl. CPC G01D 5/145; A47B 21/02; H03K 17/97

(57) ABSTRACT

A toggle control device includes a toggle, a Hall sensor, an upper housing, a lower housing, a first magnet, and a second magnet. The upper housing and the lower housing are arranged above and below the toggle, respectively, forming a body that encloses the toggle. The toggle is pivotally connected to the body and is operable to move upward or downward. The Hall sensor is arranged on the toggle. The first magnet is arranged on the upper housing, and the second magnet is arranged on the lower housing, both positioned to correspond to the location of the Hall sensor. When the toggle is actuated upward or downward, the Hall sensor detects changes in magnetic field caused by the first magnet and the second magnet, and generates a corresponding voltage signal.

### BACKGROUND OF THE DISCLOSURE

### Technical Field

The present disclosure relates to a control device, particularly a toggle control device for controlling the raising and lowering of electric furniture.

### Description of Related Art

In recent years, extended working hours have led to prolonged periods of sitting at desks, resulting in insufficient physical activity and physiological deterioration. In response, electric height-adjustable desks have emerged in the market, allowing users to adjust the desktop height at any time. With such desks, users may switch between sitting and standing while working, enabling physical activity during office hours. In addition to height-adjustable desks, other types of electric furniture that allow users to easily and freely adjust height have also gradually become more widespread.

Generally, electric furniture is equipped with multiple control buttons, such as an up button and a down button. When a user presses the up button, the electric furniture increases in height through the actuation of its internal motor and mechanism. When the user presses the down button, the furniture decreases in height in the same manner. However, such electric furniture uses fixed buttons to activate the motor in a fixed mode, and therefore lacks speed adjustment functionality during the raising or lowering of height. In other words, existing electric furniture does not allow users to adjust the speed of raising or lowering the height according to personal preferences, which results in limited flexibility and convenience.

### SUMMARY OF THE INVENTION

The present disclosure provides a toggle control device configured to control the speed at which electric furniture is raised or lowered based on the direction and travel distance of toggle movement, thereby achieving adaptive speed control.

In one embodiment, the present disclosure provides a toggle control device for controlling height adjustment of electric furniture, including:
an upper housing;
a lower housing coupled to the upper housing to form a body, the body including an internal accommodation space;
a toggle including a carrier portion, a fixed portion disposed at one end of the carrier portion and configured to secure the toggle to the body, and a movable portion disposed at another end of the carrier portion, wherein the carrier portion and the fixed portion are located within the accommodation space, and the movable portion is exposed outside the body;
a Hall sensor disposed on the carrier portion;
a first magnetic body disposed on the upper housing; and
a second magnetic body disposed on the lower housing;
wherein, when the toggle is moved upward by a first travel distance and the Hall sensor is at a first upper critical position that is closer to the first magnetic body and farther from the second magnetic body, the Hall sensor generates a first signal corresponding to the first travel distance in response to a magnetic field of the first magnetic body;
wherein, when the toggle is moved downward by the first travel distance and the Hall sensor is at a first lower critical position that is closer to the second magnetic body and farther from the first magnetic body, the Hall sensor generates a second signal corresponding to the first travel distance in response to a magnetic field of the second magnetic body.

Compared to the related art, the toggle control device of the present disclosure enables the speed at which the electric furniture is raised or lowered to increase in accordance with the increasing travel distance of the toggle movement, thereby achieving adaptive speed control.

### BRIEF DESCRIPTION OF THE DRAWINGS

FIG. 1 is an exploded view of a first embodiment of the toggle control device of the present disclosure.

FIG. 2 is an exploded view of a second embodiment of the toggle control device of the present disclosure.

FIG. 3 is an assembled view of an embodiment of the toggle control device of the present disclosure.

FIG. 4 is a cross-sectional view of a first embodiment of the toggle control device of the present disclosure.

FIG. 5 is a cross-sectional view of a second embodiment of the toggle control device of the present disclosure.

FIG. 6 is a cross-sectional view of a third embodiment of the toggle control device of the present disclosure.

FIG. 7 is a cross-sectional view of a fourth embodiment of the toggle control device of the present disclosure.

FIG. 8 is a cross-sectional view of a fifth embodiment of the toggle control device of the present disclosure.

FIG. 9 is a cross-sectional view of a sixth embodiment of the toggle control device of the present disclosure.

FIG. 10 is a schematic view of an electric height-adjustable desk with the toggle control device.

FIG. 11 is a schematic view of an electric TV stand with the toggle control device.

### DETAILED DESCRIPTION

The present disclosure discloses a toggle control device suitable for electric furniture. The toggle control device utilizes magnetic field changes resulting from a Hall sensor approaching or moving away from magnetic bodies disposed at specific locations to control the motor speed during height adjustment of the electric furniture, thereby achieving adaptive speed control. By using a Hall sensor in place of traditional mechanical buttons, design-related stroke errors may be eliminated. Moreover, the toggle control device controls the motor speed based on magnetic field variations between the Hall sensor and the magnetic bodies, which helps eliminate sensitivity differences within the detection range of the sensor, as well as inconsistencies in the magnetic characteristics of the magnetic bodies, thereby allowing stable performance regardless of part tolerances or assembly variations.

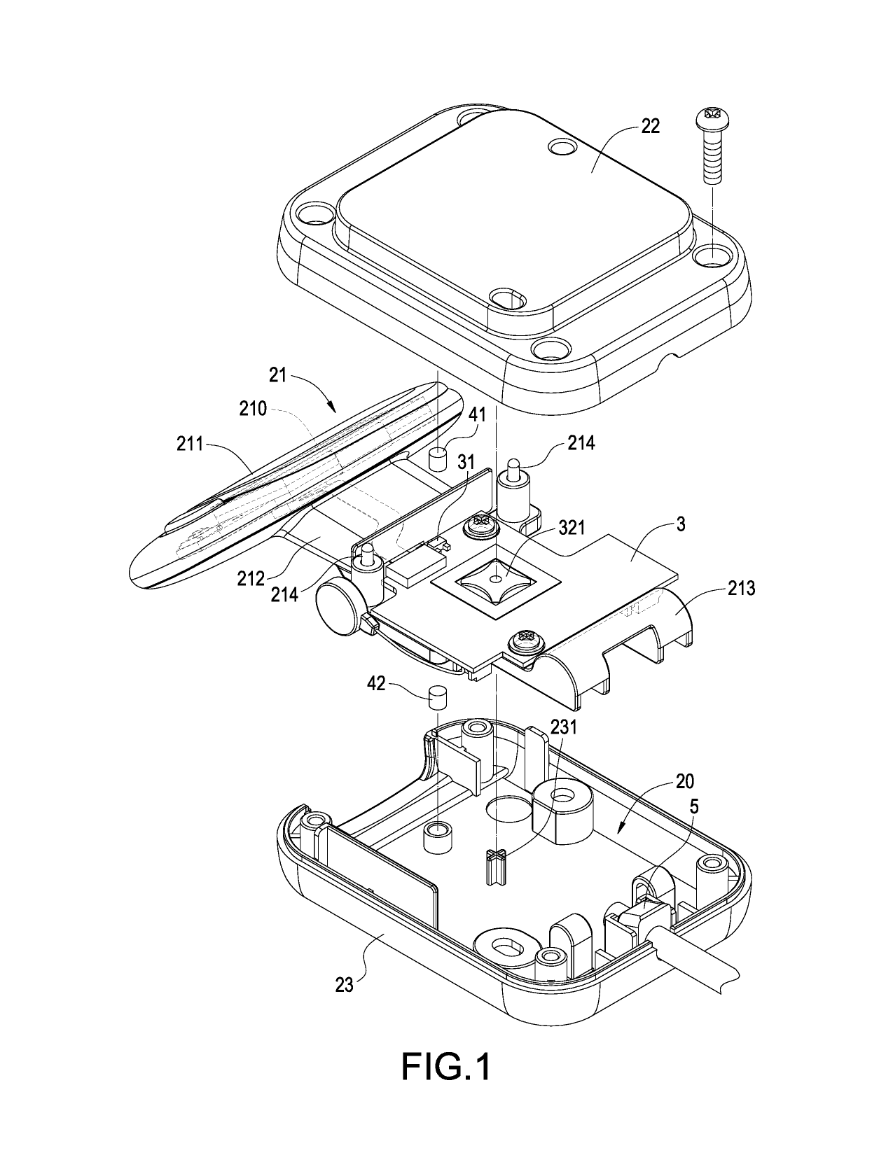

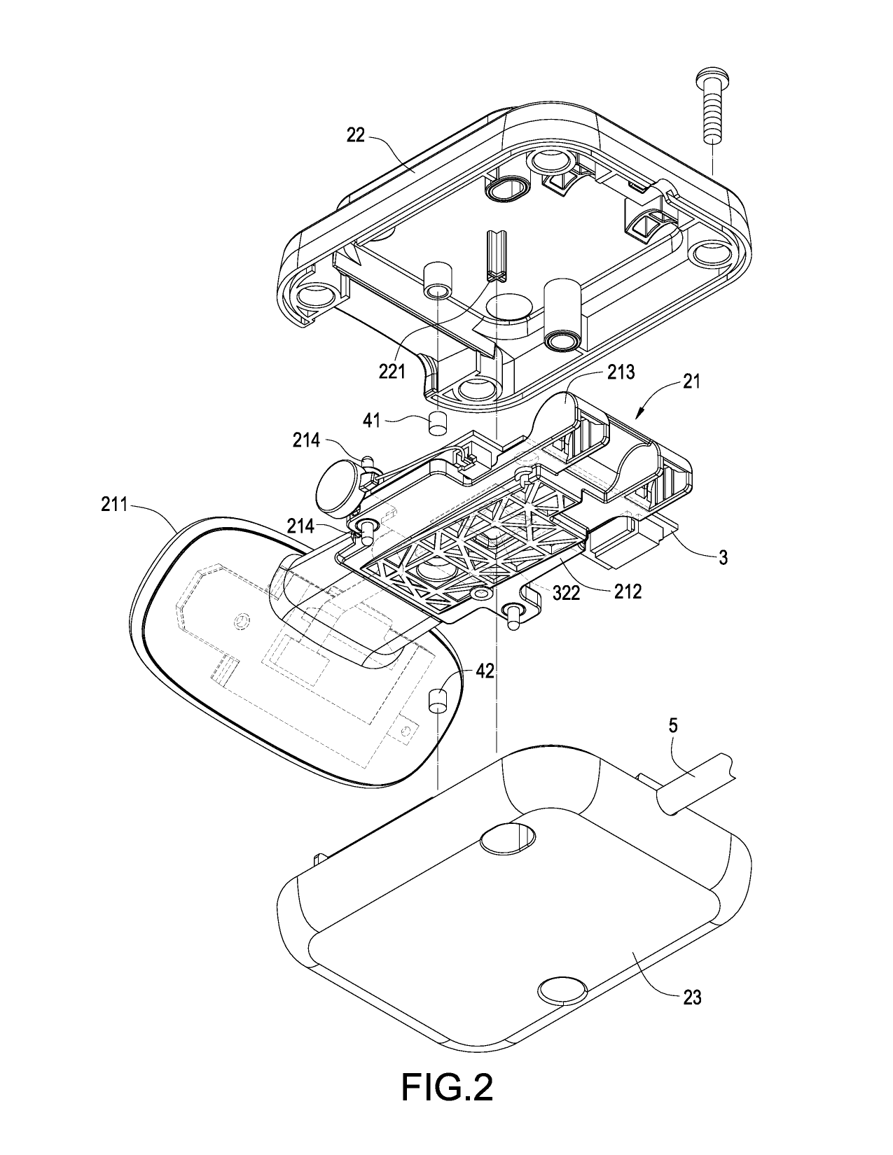

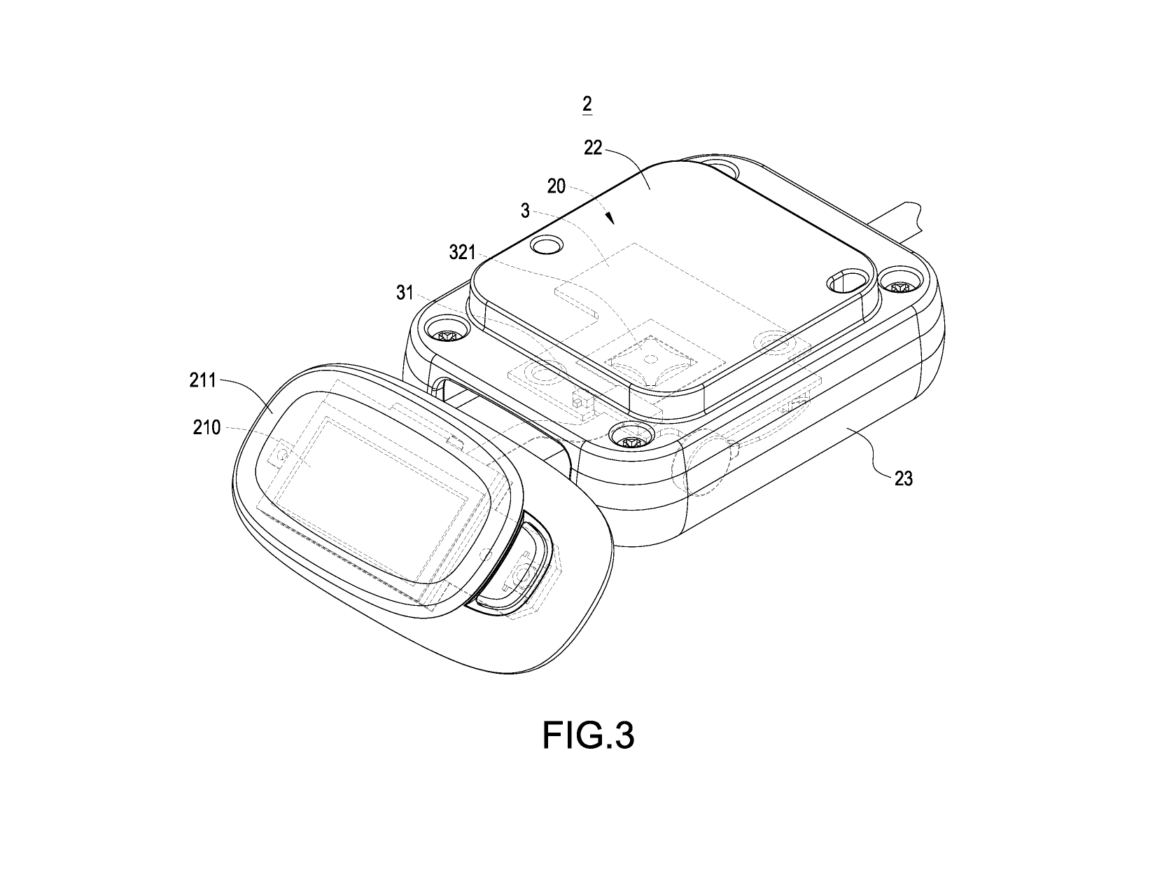

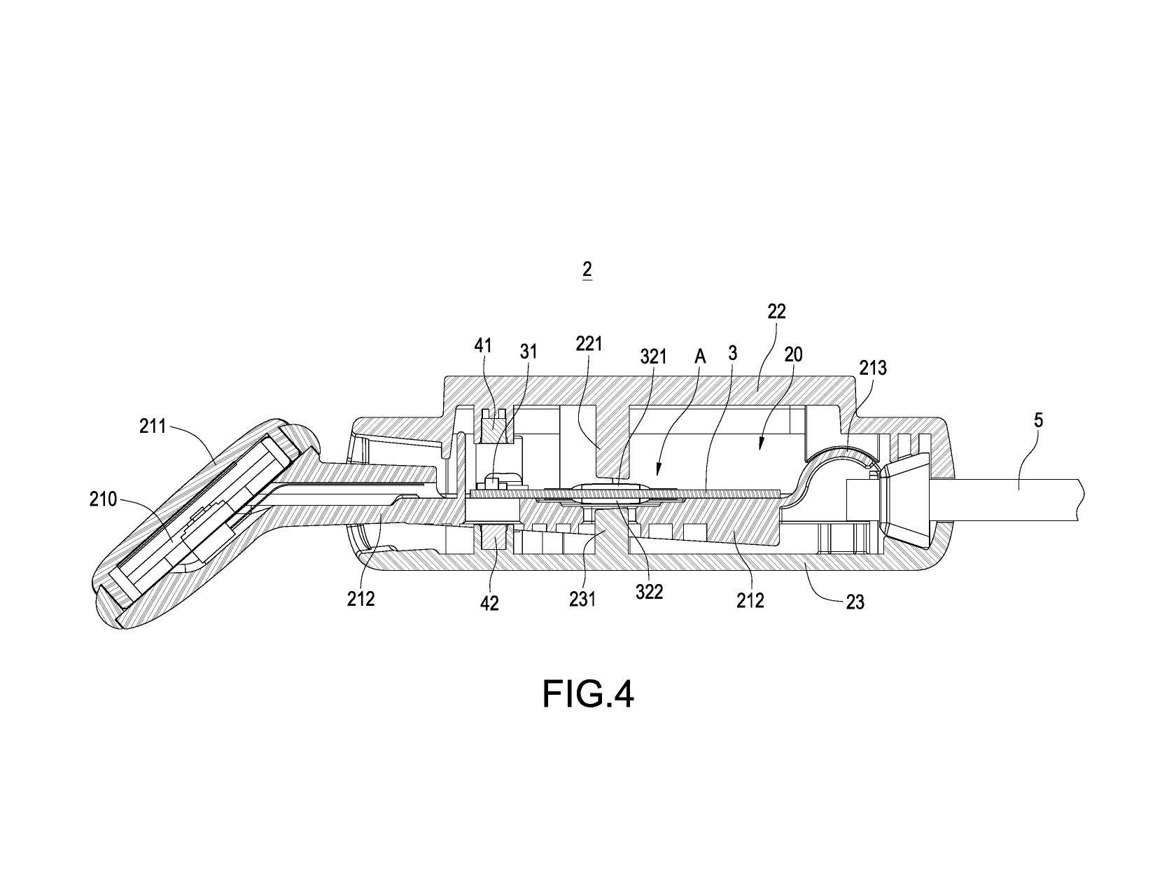

Referring to FIGS. 1 to 4, FIG. 1 is an exploded view of a first embodiment of the toggle control device of the present disclosure. FIG. 2 is an exploded view of a second embodiment of the toggle control device of the present disclosure. FIG. 3 is an assembled view of an embodiment of the toggle control device of the present disclosure. FIG. 4 is a cross-sectional view of a first embodiment of the toggle control device of the present disclosure.

The present disclosure discloses a toggle control device 2 configured to connect to electric furniture (e.g., an electric height-adjustable desk) and to control the speed during height adjustment of the electric furniture. Specifically, the toggle control device 2 may be fixedly installed on one side of the electric furniture. In the present disclosure, a user may operate a toggle 21 on the toggle control device 2 by moving it upward or downward. When the toggle 21 is moved upward under force, the electric furniture receives a corresponding signal and raises its height at a corresponding speed. When the toggle 21 is moved downward under force, the electric furniture receives a corresponding signal and lowers its height at a corresponding speed. A technical feature of the present disclosure lies in that, based on the travel distance of the toggle 21 moved upward or downward by the user (i.e., the extent of upward or downward movement), the electric furniture adjusts the speed of raising or lowering the height (the raising or lowering speed) accordingly.

Specifically, traditional electric furniture primarily uses fixed buttons (e.g., an up button and a down button) to raise or lower the height. However, such electric furniture lacks speed adjustment functionality. When the user presses the up or down button, the electric furniture adjusts its height at a fixed speed. The present disclosure replaces the fixed buttons of traditional electric furniture with the toggle control device 2 incorporating a Hall sensor 31, allowing the user to freely determine the speed for raising or lowering the height of the electric furniture based on the travel distance of the toggle control device 2.

As shown in FIGS. 1-4, the toggle control device 2 includes at least a toggle 21, a Hall sensor 31, an upper housing 22, a lower housing 23, a first magnetic body 41, and a second magnetic body 42. The upper housing 22 and lower housing 23 are configured together to form a body that encloses the toggle 21. The interior of the body defines an accommodation space 20 for housing at least a portion of the toggle 21. The Hall sensor 31 is disposed on the toggle 21. When the toggle 21 is actuated by the user, the Hall sensor 31 moves within the accommodation space 20 in correspondence with the direction of toggle movement. More specifically, the toggle control device 2 is connectable to the electric furniture (not illustrated) to be controlled. When the toggle 21 is moved upward or downward under force, only the toggle 21 moves within the accommodation space 20 of the body, while the body (i.e., the upper housing 22 and the lower housing 23) remains stationary and does not move with the toggle 21.

In one embodiment, the toggle control device 2 further includes a wire 5. The toggle control device 2 may receive power through the wire 5 and may transmit control signals to a controller (not illustrated) of the electric furniture via the wire 5.

One end of the toggle 21 includes a fixed portion 213, and the other end of the toggle 21 includes a movable portion. The toggle 21 is fixed to one side of the interior of the body via the fixed portion 213. The movable portion includes a handle 211 for user operation. Because one end of the toggle 21 is fixed to the body by the fixed portion 213, the user may operate a handle 211 at the opposite end of the toggle 21 to pivot the toggle 21 upward or downward. In this case, the toggle 21 swings upward or downward under force about the fixed portion 213 as a pivot point. In other embodiments, the direction in which the fixed portion 213 is secured to the body may be changed, allowing the toggle 21 to swing leftward or rightward about the fixed portion 213 under force. However, this is not limiting. For ease of understanding, the following description uses the example in which the user applies force to the handle 211 of the toggle 21 to move it upward or downward.

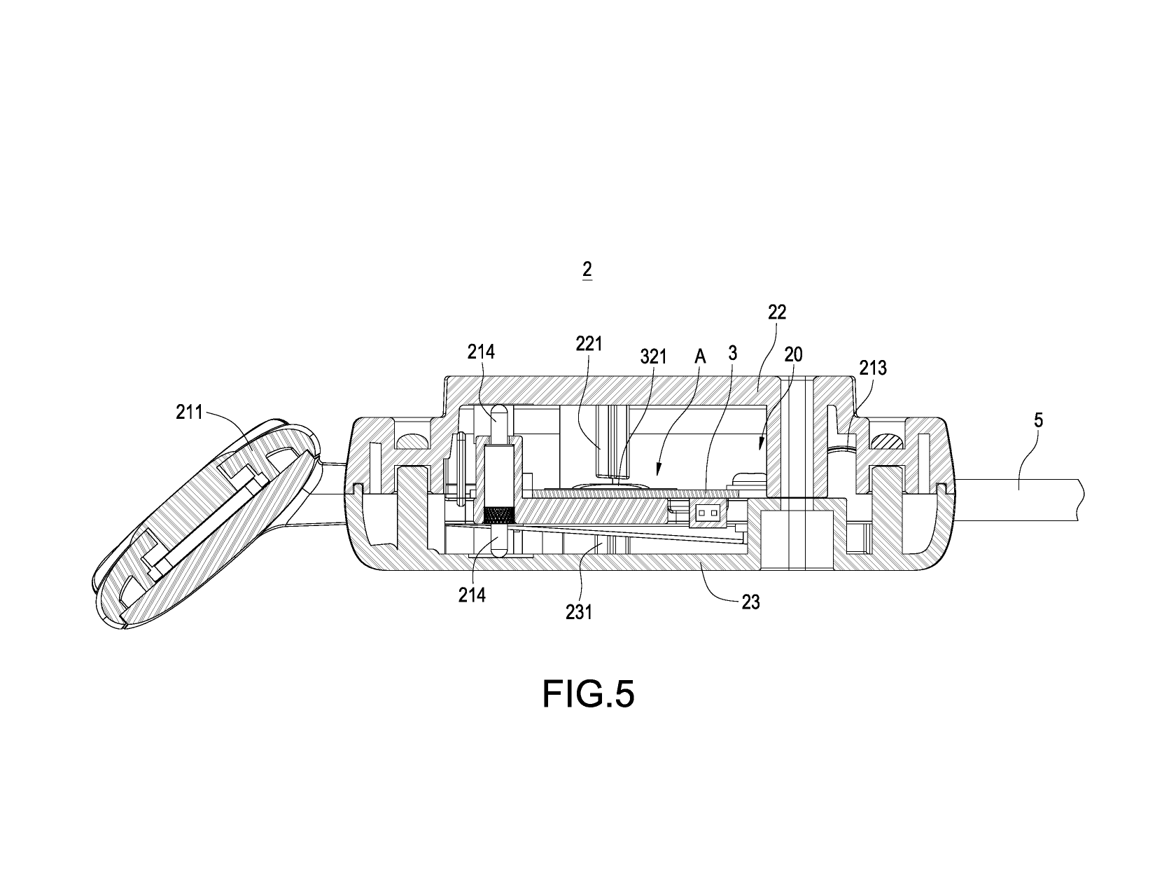

As shown in FIGS. 1 and 2, the Hall sensor 31 is disposed on the toggle 21. The first magnetic body 41 is disposed on the upper housing 22 at a position corresponding to the position of the Hall sensor 31 on the toggle 21. The second magnetic body 42 is disposed on the lower housing 23 at a position also corresponding to the position of the Hall sensor 31 on the toggle 21. In one embodiment, when the Hall sensor 31 is at an initial position (i.e., when the toggle 21 is not under force, and the Hall sensor 31 is located at initial position A as shown in FIG. 5), the first magnetic body 41, the Hall sensor 31, and the second magnetic body 42 are arranged vertically or approximately vertically.

In one embodiment, the first magnetic body 41 and the second magnetic body 42 have opposite magnetic polarities. When the Hall sensor 31 is at the initial position A, the linear distance between the first magnetic body 41 and the Hall sensor 31 is equal to the linear distance between the second magnetic body 42 and the Hall sensor 31. In one example, the first magnetic body 41 is an N-pole magnet and the second magnetic body 42 is an S-pole magnet, and their respective linear distances from the Hall sensor 31 are equal when the Hall sensor 31 is at the initial position A, with the linear distance between first magnetic body 41 and Hall sensor 31 equal to that between second magnetic body 42 and Hall sensor 31. When the toggle 21 is not under force and the Hall sensor 31 is at initial position A, the magnetic field sensed by Hall sensor 31 is zero.

As described above, when the toggle 21 is moved upward or downward under force, the body remains fixed to the electric furniture and does not move. Accordingly, the first magnetic body 41 and the second magnetic body 42 also remain stationary. Therefore, when the toggle 21 is moved upward under force, the Hall sensor 31 moves upward along with the toggle 21, approaching the first magnetic body 41 on the upper housing 22. Conversely, when the toggle 21 is moved downward under force, the Hall sensor 31 moves downward along with the toggle 21, approaching the second magnetic body 42 on the lower housing 23.

More specifically, when the user moves the toggle 21 upward, the Hall sensor 31 moves upward (i.e., in the direction toward the upper housing 22) along with the toggle 21, such that the linear distance between the first magnetic body 41 and the Hall sensor 31 becomes shorter than the linear distance between the second magnetic body 42 and the Hall sensor 31. At this time, the magnetic field sensed by the Hall sensor 31 is primarily influenced by the first magnetic body 41, resulting in a first change. Conversely, when the user moves the toggle 21 downward, the Hall sensor 31 moves downward (i.e., in the direction toward the lower housing 23) along with the toggle 21, such that the linear distance between the second magnetic body 42 and the Hall sensor 31 becomes shorter than the linear distance between the first magnetic body 41 and the Hall sensor 31. At this time, the magnetic field sensed by the Hall sensor 31 is primarily influenced by the second magnetic body 42, resulting in a second change.

In one embodiment, the toggle control device 2 receives the power required for operation from an external source or from the connected electric furniture, and supplies a constant current to the Hall sensor 31 to ensure continuous operation. As previously described, since the first magnetic body 41 and the second magnetic body 42 have opposite polarities and are equidistant from the Hall sensor 31, the magnetic field sensed by the Hall sensor 31 is zero when the toggle 21 is not being operated by the user. When the Hall sensor 31 moves upward with the toggle 21 toward the first magnetic body 41, or downward toward the second magnetic body 42, the resulting magnetic field is influenced by the respective magnetic body, causing a potential difference at the output terminal of the Hall sensor 31 (not illustrated). In the present disclosure, this potential difference serves as a signal related to the distance between the Hall sensor 31 and the first magnetic body 41/the second magnetic body 42. Accordingly, the toggle control device 2 generates a voltage signal of corresponding magnitude through the Hall sensor 31 based on magnetic field changes caused by the first and second magnetic bodies 41, 42, and controls the connected electric furniture—either directly or indirectly—based on the voltage signal. In this way, the toggle control device 2 adjusts the raising or lowering speed of the electric furniture in response to the travel distance of the toggle 21 as operated by the user.

In one embodiment, the toggle 21 of the toggle control device 2 is an elongated structure that includes a movable portion (with a handle 211 provided thereon), a carrier portion 212, and a fixed portion 213. As shown in FIGS. 1 to 4, the fixed portion 213 is disposed at one end of the carrier portion 212, while the movable portion is disposed at the opposite end of the carrier portion 212. The fixed portion 213 and the carrier portion 212 are positioned within the accommodation space 20 of the body, and the movable portion extends outward beyond the accommodation space 20. The handle 211 is disposed on the movable portion, that is, on one side of the carrier portion 212, and extends beyond the accommodation space 20 of the body to allow for user operation. The fixed portion 213 is disposed at the end of the carrier portion 212 opposite the movable portion, and serves to secure the toggle 21 to the body.

The toggle control device 2 further includes a circuit board 3. The circuit board 3 is disposed on the carrier portion 212 of the toggle 21. In one embodiment, the Hall sensor 31 is electrically connected to the circuit board 3 and is mounted on the carrier portion 212 via the circuit board 3. In this embodiment, the toggle control device 2 supplies a constant current to the circuit board 3 which in turn supplies the current to the Hall sensor 31, enabling the Hall sensor 31 to operate continuously during activation of the toggle control device 2. In one embodiment, the toggle control device 2 supplies the constant current to the circuit board 3 via an internal or external power source. In another embodiment, the toggle control device 2 obtains power from the connected electric furniture to provide the constant current to the circuit board 3.

In one embodiment, the toggle control device 2 further includes a transmission unit (not illustrated). The transmission unit is electrically connected to the circuit board 3, and is further electrically connected to the Hall sensor 31 through the circuit board 3. In this embodiment, the toggle control device 2 transmits the signals generated by the Hall sensor 31 to the connected electric furniture via the transmission unit, either in a wired or wireless manner. This enables a processor of the electric furniture to control the raising or lowering speed (the speed of raising or lowering the height) based on the magnetic field sensed by the Hall sensor 31 and the corresponding signals.

In one embodiment, the toggle control device 2 further includes a reset structure 214 disposed on the carrier portion 212. As shown in FIG. 1, two reset structures 214 are provided on opposite sides of the carrier portion 212. Each reset structure 214 contains a spring (not illustrated), and includes an upward-extending upper protruding column and a downward-extending lower protruding column extending from the carrier portion 212. The upper protruding column abuts the inner surface of the upper housing 22, while the lower protruding column abuts the inner surface of the lower housing 23. When the toggle 21 is not under force, the upper and lower protruding columns of the reset structure 214 press against the upper housing 22 and the lower housing 23, respectively, thereby supporting the carrier portion 212 and maintaining the toggle 21 in its initial position (e.g., initial position A shown in FIG. 5). When the user moves the toggle 21 upward to a first position, the upper protruding column of the reset structure 214 is compressed against the upper housing 22, thereby compressing the internal spring within the reset structure 214. This generates an upward reaction force against the upper housing 22. When the user releases the toggle 21, the stored energy in the spring restores the toggle 21 from the first position back to the initial position A. Conversely, when the user moves the toggle 21 downward to a second position, the lower protruding column of the reset structure 214 is compressed against the lower housing 23, similarly compressing the internal spring and generating a downward reaction force against the lower housing 23. Upon release, the toggle 21 is returned to the initial position A from the second position by the spring force. When the toggle 21 returns to the initial position A, the controller of the electric furniture may determine that the user operation has ended (i.e., the magnetic field sensed by the Hall sensor 31 is zero) based on the voltage signal provided by the toggle control device 2 and stop the motor accordingly. At this point, the raising or lowering movement of the electric furniture ceases.

In the present disclosure, the toggle control device 2 further includes an upper trigger switch 321 and a lower trigger switch 322. In the embodiments shown in FIGS. 1 to 4, the upper trigger switch 321 is electrically connected to one side of the circuit board 3, and the lower trigger switch 322 is electrically connected to the opposite side of the circuit board 3. More specifically, the upper trigger switch 321 is disposed on a first side of the circuit board 3 facing the upper housing 22. An upper protrusion 221 extends from the inner surface of the upper housing 22 toward the circuit board 3. The mounting position of the upper trigger switch 321 on the circuit board 3 corresponds to the position of the upper protrusion 221 on the inner surface of the upper housing 22. The lower trigger switch 322 is disposed on a second side of the circuit board 3 facing the lower housing 23. A lower protrusion 231 extends from the inner surface of the lower housing 23 toward the circuit board 3. The mounting position of the lower trigger switch 322 on the circuit board 3 corresponds to the position of the lower protrusion 231 on the inner surface of the lower housing 23.

In the present disclosure, when the user moves the toggle 21 upward by a first travel distance, the Hall sensor 31 approaches the first magnetic body 41 on the upper housing 22 and moves away from the second magnetic body 42 on the lower housing 23. At this time, the magnetic field sensed by the Hall sensor 31 changes accordingly, and a voltage signal with a corresponding signal strength (e.g., a first signal) is output. In response, the electric furniture connected to the toggle control device 2 raises its height at a first speed. When the user continues to move the toggle 21 upward by a second travel distance, the upper trigger switch 321 is actuated by contacting the upper protrusion 221 on the upper housing 22. At this point, either the upper trigger switch 321 or a controller (not illustrated) generates a corresponding control signal (e.g., a second signal), causing the electric furniture connected to the toggle control device 2 to raise its height at a second speed. Similarly, when the user moves the toggle 21 downward by the first travel distance, the Hall sensor 31 approaches the second magnetic body 42 on the lower housing 23 and moves away from the first magnetic body 41 on the upper housing 22. The magnetic field sensed by the Hall sensor 31 changes accordingly, and a voltage signal with a corresponding signal strength (e.g., a third signal) is output. In response, the electric furniture lowers its height at the first speed. When the user continues to move the toggle 21 downward by the second travel distance, the lower trigger switch 322 is actuated by contacting the lower protrusion 231 on the lower housing 23. At this time, either the lower trigger switch 322 or the controller (not illustrated) generates a corresponding control signal (e.g., a fourth signal), causing the electric furniture to lower its height at the second speed.

In one embodiment, the first travel distance is shorter than the second travel distance, and the first speed is slower than the second speed.

In one embodiment, when the user moves the toggle 21 upward or downward by the first travel distance, the electric furniture connected to the toggle control device 2 raises or lowers its height at a medium speed (also referred to as half speed). When the user moves the toggle 21 upward or downward by the second travel distance (i.e., when the upper trigger switch 321 contacts the upper protrusion 221 or the lower trigger switch 322 contacts the lower protrusion 231), the electric furniture raises or lowers its height at full speed.

In one embodiment, the upper trigger switch 321 and the lower trigger switch 322 are metal domes or snap domes. When the toggle 21 moves upward to a position where the upper protrusion 221 presses against the upper trigger switch 321, the upper trigger switch 321 is actuated, causing the upper trigger switch 321 or the controller of the toggle control device 2 to generate a corresponding control signal. Similarly, when the toggle 21 moves downward to a position where the lower protrusion 231 presses against the lower trigger switch 322, the lower trigger switch 322 is actuated, causing the lower trigger switch 322 or the controller to generate a corresponding control signal.

As shown in FIG. 3, a display panel 210 may also be provided within the handle 211 of the toggle 21. The display panel 210 is electrically connected to the circuit board 3 on the carrier portion 212. In one embodiment, the display panel 210 shows the current travel of the toggle 21 (e.g., whether it is being moved upward or downward, and the extent of the movement). In another embodiment, the display panel 210 displays whether the upper trigger switch 321 or the lower trigger switch 322 is currently actuated. In yet another embodiment, the display panel 210 indicates the current height of the electric furniture during adjustment. In a further embodiment, the display panel 210 shows the speed at which the electric furniture is currently adjusting its height. The foregoing are merely specific implementation examples, and the display panel 210 may be configured to show different information at different time according to user settings, thereby assisting the user in configuring the toggle control device 2 and controlling the electric furniture.

Referring to FIGS. 5 to 9, these are cross-sectional views of the second to sixth embodiments of the toggle control device of the present disclosure.

As shown in FIG. 5, when the user is not operating the device, the toggle 21 maintains the Hall sensor 31 at the initial position A with the support of the fixed portion 213 and the reset structure 214. As previously described, when the Hall sensor 31 is at the initial position A (i.e., the user has not actuated the toggle 21), the magnetic field is zero. At this time, the Hall sensor 31 does not generate a signal, or the signal generated has a signal strength corresponding to a zero magnetic field. As a result, the electric furniture connected to the toggle control device 2 does not perform any height adjustment.

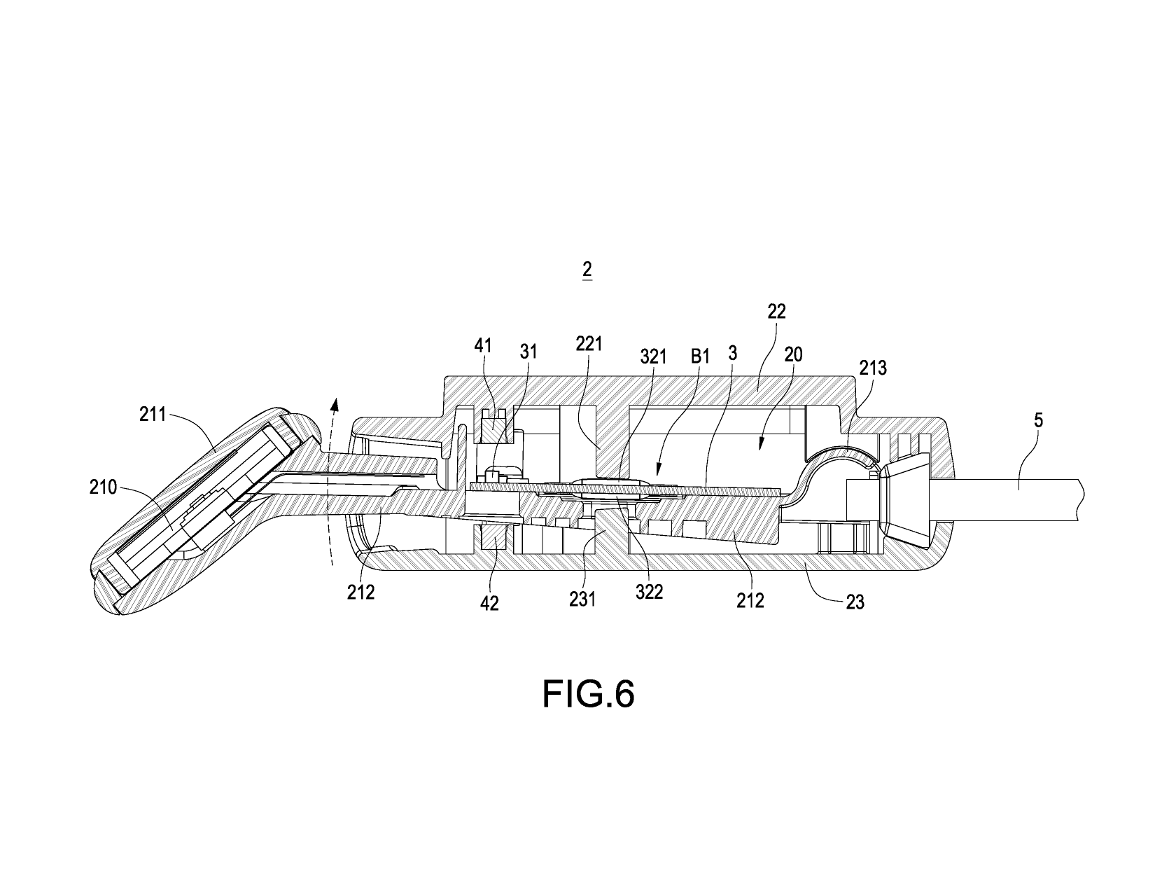

As shown in FIG. 6, when the user moves the toggle 21 upward by the first travel distance, the Hall sensor 31 moves upward to a first upper critical position B1. In the embodiment of FIG. 6, when the Hall sensor 31 is at the first upper critical position B1, the linear distance between the Hall sensor 31 and the first magnetic body 41 is less than that between the Hall sensor 31 and the second magnetic body 42, and neither the upper trigger switch 321 nor the lower trigger switch 322 is triggered. When the toggle 21 moves upward by the first travel distance, the Hall sensor 31 generates a voltage signal with a corresponding signal strength (e.g., a first signal) based on the magnetic field change caused by first magnetic body 41. The signal strength of the first signal corresponds to the first travel distance. In this embodiment, the electric furniture connected to the toggle control device 2 controls the motor to rotate at a corresponding speed (e.g., half speed in forward rotation) to raise the height based on this first signal.

In one embodiment, the first magnetic body 41 is an N-pole magnet, and the second magnetic body 42 is an S-pole magnet. When the user moves the toggle 21 upward by the first travel distance, the Hall sensor 31 approaches the upper first magnetic body 41 and moves away from the lower second magnetic body 42 (i.e., reaching the first upper critical position B1). At this point, the magnetic field sensed by the Hall sensor 31 is influenced by the upper N-pole magnet, resulting in a first change. Accordingly, the signal strength of the generated voltage signal changes in response. Thus, the controller may determine that the user has moved the toggle 21 upward by the first travel distance based on the signal strength of the voltage signal from the Hall sensor 31. When the user releases the toggle 21, it returns to the initial position A via the reaction force provided by the reset structure 214. The magnetic field sensed by the Hall sensor 31 then becomes zero, causing the electric furniture to stop adjusting its height.

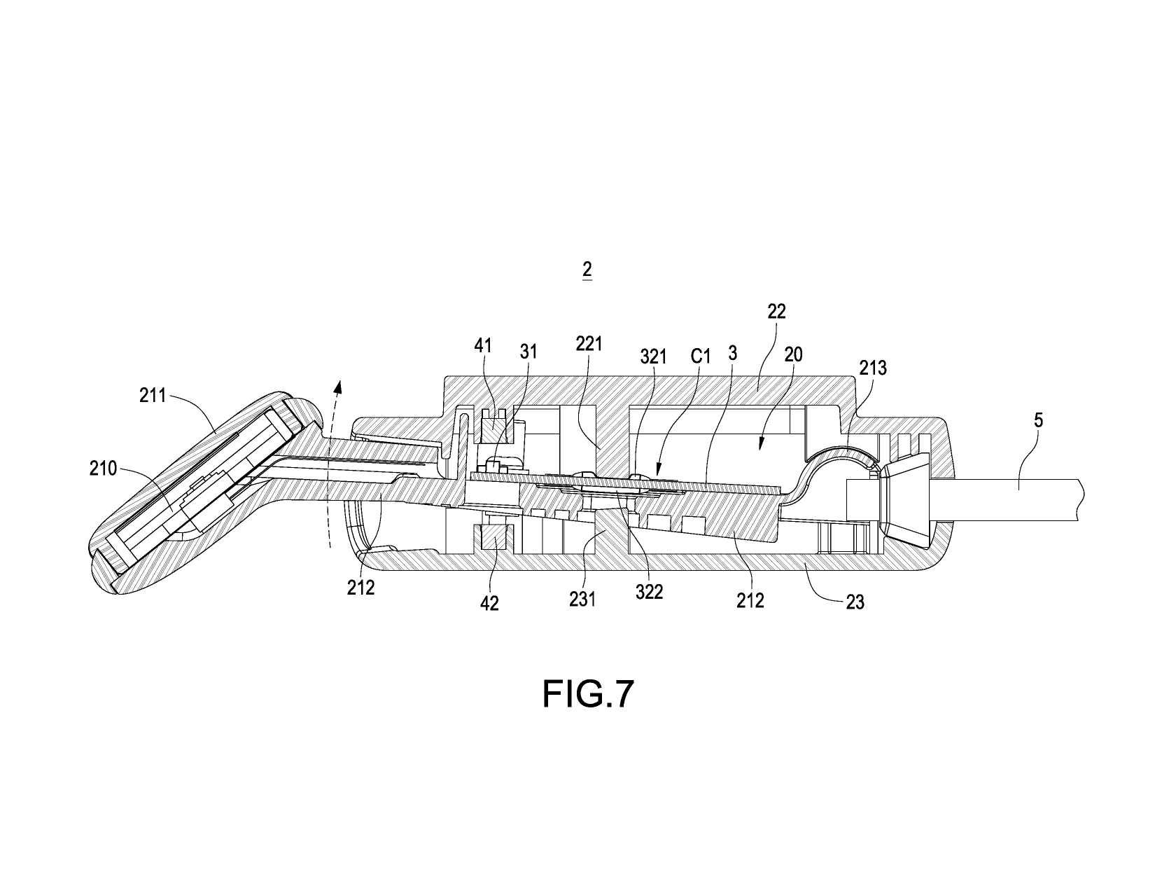

As shown in FIG. 7, when the user further moves the toggle 21 upward by the second travel distance, the Hall sensor 31 moves upward to a second upper critical position C1. Specifically, the second travel distance is greater than the first travel distance, meaning that in the embodiment of FIG. 7, the extent of upward movement is greater than that in FIG. 6.

When the Hall sensor 31 is at the second upper critical position C1, the linear distance between the Hall sensor 31 and the first magnetic body 41 is less than that between the Hall sensor 31 and the second magnetic body 42. At this point, the upper trigger switch 321 is triggered by the upper protrusion 221 on the inner side of the upper housing 22. When the toggle 21 moves upward by the second travel distance and causes the upper trigger switch 321 to be triggered, the controller of the electric furniture generates a corresponding control signal (e.g., a second signal) based on the triggering of the upper trigger switch 321. The second signal corresponds to the second travel distance. In this embodiment, the electric furniture controls the motor to rotate at a corresponding speed (e.g., full speed in forward rotation) to raise the height based on the second signal.

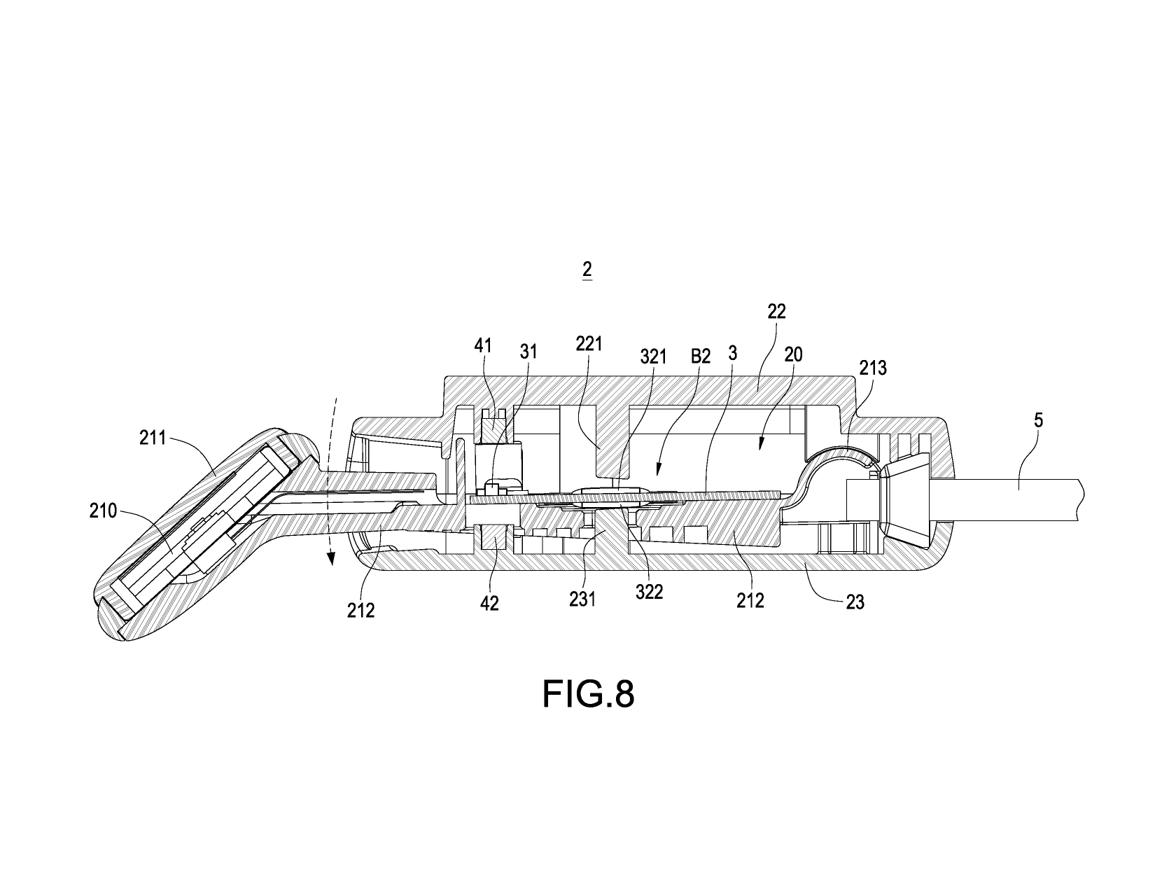

As shown in FIG. 8, when the user moves the toggle 21 downward by the first travel distance, the Hall sensor 31 moves downward to a first lower critical position B2. In the embodiment of FIG. 8, when the Hall sensor 31 is at the first lower critical position B2, the linear distance between the Hall sensor 31 and the second magnetic body 42 is less than that between the Hall sensor 31 and the first magnetic body 41, and neither the upper trigger switch 321 nor the lower trigger switch 322 is triggered. When the toggle 21 moves downward by the first travel distance, the Hall sensor 31 generates a voltage signal with a corresponding signal strength (e.g., a third signal) based on the magnetic field change caused by the second magnetic body 42. The signal strength of the third signal corresponds to the first travel distance. In this embodiment, the electric furniture connected to the toggle control device 2 controls the motor to rotate at a corresponding speed (e.g., half speed in reverse rotation) to lower the height based on the third signal.

In one embodiment, the first magnetic body 41 is an N-pole magnet, and the second magnetic body 42 is an S-pole magnet. When the user moves the toggle 21 downward by the first travel distance, the Hall sensor 31 approaches the second magnetic body 42 located below and moves away from the first magnetic body 41 located above (i.e., at the first lower critical position B2). At this point, the magnetic field sensed by the Hall sensor 31 is influenced by the lower S-pole magnet, resulting in a second change and a corresponding change in the signal strength of the generated voltage signal. Accordingly, the controller may determine that the user has moved the toggle 21 downward by the first travel distance based on the signal strength of the voltage signal from the Hall sensor 31. When the user releases the force, the toggle 21 returns to the initial position A by the reaction force of the reset structure 214, and the magnetic field sensed by the Hall sensor 31 returns to zero, causing the electric furniture to stop adjusting its height.

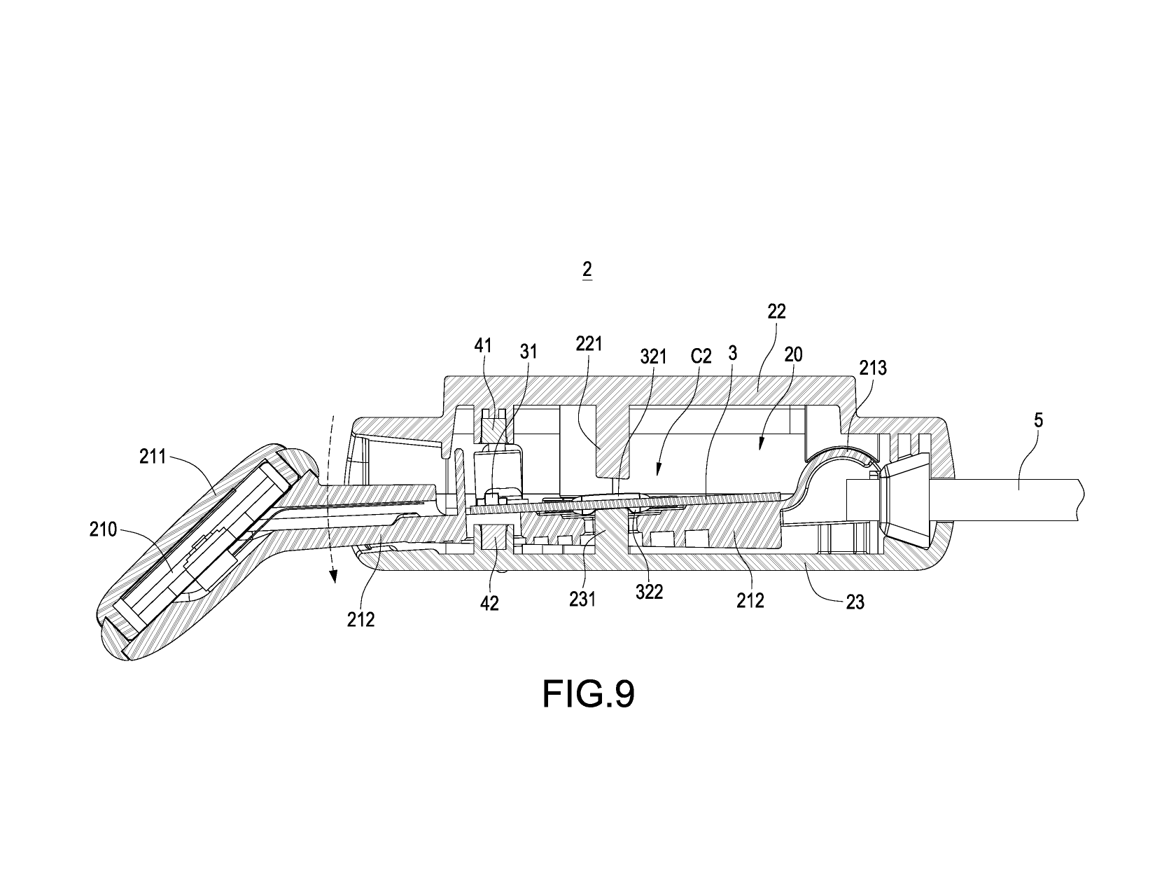

As shown in FIG. 9, when the user further moves the toggle 21 downward by the second travel distance, the Hall sensor 31 moves downward to a second lower critical position C2. Specifically, the second travel distance is greater than the first travel distance, meaning that the extent of downward movement in the embodiment of FIG. 9 is greater than that in the embodiment of FIG. 8.

In the embodiment of FIG. 9, when the Hall sensor 31 is at the second lower critical position C2, the linear distance between the Hall sensor 31 and the second magnetic body 42 is less than that between the Hall sensor 31 and the first magnetic body 41. At this point, the lower trigger switch 322 is triggered by the lower protrusion 231 on the inner side of the lower housing 23. When the toggle 21 moves downward by the second travel distance and causes the lower trigger switch 322 to be triggered, the controller of the toggle control device 2 or the controller of the electric furniture generates a corresponding control signal (e.g., a fourth signal) based on the triggering of the lower trigger switch 322. The fourth signal corresponds to the second travel distance. In this embodiment, the electric furniture controls the motor to rotate at a corresponding speed (e.g., full speed in reverse rotation) to lower the height based on the fourth signal.

Specifically, when the user wishes to slowly raise the height of the electric furniture, the toggle 21 may be slightly moved upward (e.g., by the first travel distance), in which case the toggle control device 2 controls the electric furniture to raise at a slow speed (e.g., half speed) based on the first change in the magnetic field sensed by the Hall sensor 31. When the user wishes to raise the height quickly, the toggle 21 may be moved upward significantly (e.g., by the second travel distance), and the toggle control device 2 controls the electric furniture to raise at a high speed (e.g., full speed) based on the triggering of the upper trigger switch 321. When the user wishes to slowly lower the height of the electric furniture, the toggle 21 may be slightly moved downward (e.g., by the first travel distance), and the toggle control device 2 controls the electric furniture to lower at a slow speed (e.g., half speed) based on the second change in the magnetic field sensed by the Hall sensor 31. When the user wishes to lower the height quickly, the toggle 21 may be moved downward significantly (e.g., by the second travel distance), and the toggle control device 2 controls the electric furniture to lower at a high speed (e.g., full speed) based on the triggering of the lower trigger switch 322.

In this disclosure, the Hall sensor 31 continually generates voltage signals (e.g., every 1 ms, 5 ms, or 10 ms) based on the sensed magnetic field. This allows the toggle control device 2 to control the electric furniture to adjust its height at a slow speed (e.g., half speed) based on the voltage signals. On the other hand, the upper trigger switch 321 and the lower trigger switch 322 continually generate control signals during their activation, enabling the toggle control device 2 to control the electric furniture to adjust its height at a high speed based on these control signals.

In one embodiment, the controller of the toggle control device 2 or the controller of the electric furniture generates corresponding control commands based on signals from the Hall sensor 31 and/or the upper trigger switch 321 and the lower trigger switch 322. These control commands specify the rotation direction and rotation speed of the motor of the electric furniture. More specifically, the motor’s rotation direction includes forward rotation for raising the height and reverse rotation for lowering the height, and the rotation speed includes at least half speed (e.g., 50% of the rated speed) and full speed (e.g., 100% of the rated speed). Accordingly, the controller may convert the sensing result of the Hall sensor 31 and/or the triggering status of the upper trigger switch 321 and the lower trigger switch 322 into corresponding control commands, thereby controlling the motor to rotate in the appropriate direction and at the appropriate speed, achieving adaptive control for slow raising, fast raising, slow lowering, and fast lowering of the electric furniture.

In the present disclosure, the toggle control device 2 may be initially configured by the user. In one embodiment, the display panel 210 on the handle 211 is a touchscreen, enabling the user to perform the initial configuration of the toggle control device 2 via the display panel 210. For example, when the toggle 21 is not being moved (i.e., when the magnetic field sensed by the Hall sensor 31 is zero), the user may set the current position of the Hall sensor 31 as the initial position A via the display panel 210. Then, when the user moves the toggle 21 upward by the first travel distance such that the Hall sensor 31 senses the first magnetic field or outputs a voltage signal having a first signal strength, the user may set the current position of the Hall sensor 31 as the first upper critical position B1 via the display panel 210. Next, when the user moves the toggle 21 upward by the second travel distance such that the upper trigger switch 321 is triggered by the upper protrusion 221 of the upper housing 22, the user may set the current position of the Hall sensor 31 as the second upper critical position C1 via the display panel 210. Conversely, when the user moves the toggle 21 downward by the first travel distance such that the Hall sensor 31 senses the second magnetic field or outputs a voltage signal having a second signal strength, the user may set the current position of the Hall sensor 31 as the first lower critical position B2 via the display panel 210. Then, when the user moves the toggle 21 downward by the second travel distance such that the lower trigger switch 322 is triggered by the lower protrusion 231 of the lower housing 23, the user may set the current position of the Hall sensor 31 as the second lower critical position C2 via the display panel 210.

In the present disclosure, after the user completes the initial setting, the controller of the toggle control device 2 or the electric furniture records the signal strengths of the voltage signals output by the Hall sensor 31 at the initial position A, the first upper critical position B1, the second upper critical position C1, the first lower critical position B2, and the second lower critical position C2, as well as the signal content generated when the upper trigger switch 321 or the lower trigger switch 322 is triggered. Accordingly, when the user moves the toggle 21 and causes the Hall sensor 31 and/or the upper trigger switch 321 or lower trigger switch 322 to generate corresponding signals, the controller may perform corresponding control operations on the electric furniture.

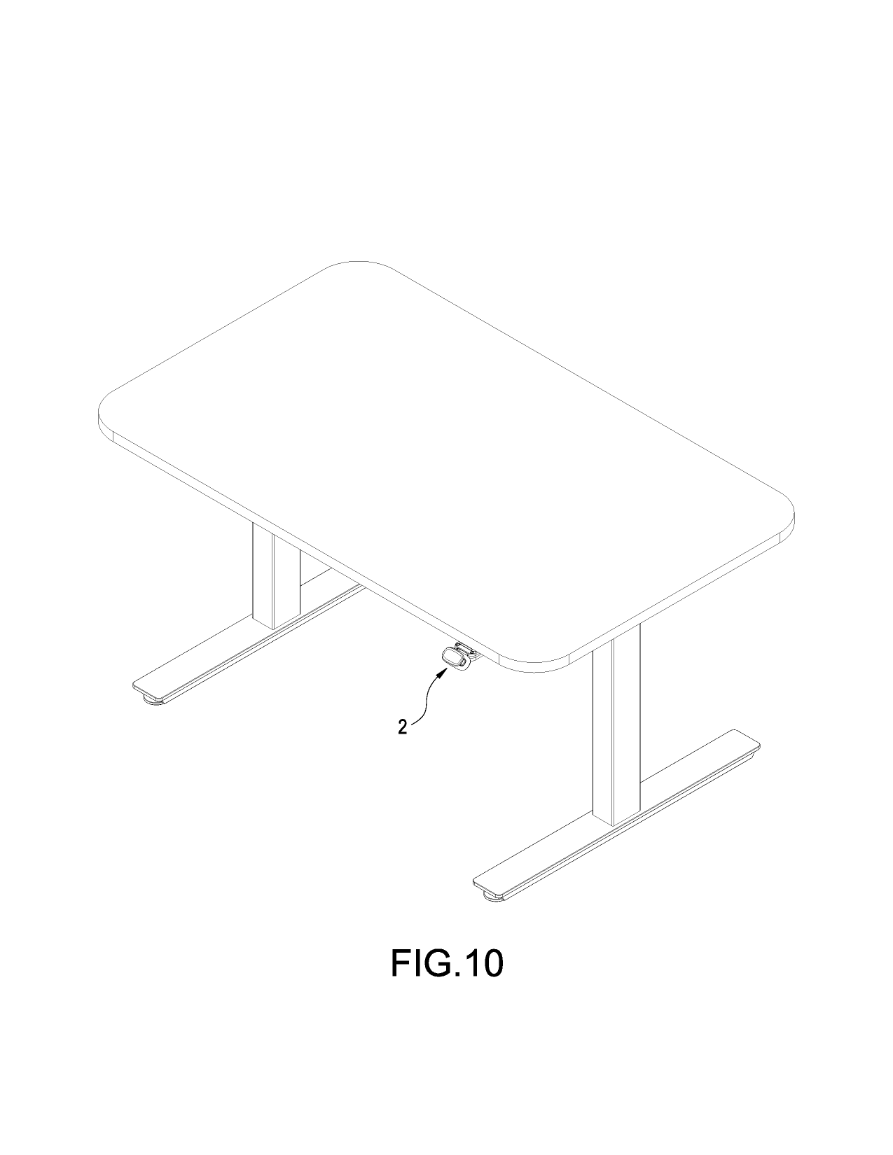

Referring to FIG. 10, a schematic view of an electric height-adjustable desk equipped with the toggle control device is shown. As illustrated, the toggle control device 2 of the present disclosure may be connected to the electric height-adjustable desk 1 to adjust its height. For example, when the user moves the toggle 21 of the toggle control device 2 upward by the first travel distance (i.e., the Hall sensor 31 approaches the first magnetic body 41), the desk 1 raises the desktop height at a low speed; when the user moves the toggle 21 upward by the second travel distance (i.e., the upper trigger switch 321 is triggered), the desk 1 raises the desktop height at a high speed. When the user moves the toggle 21 downward by the first travel distance (i.e., the Hall sensor 31 approaches the second magnetic body 42), the desk 1 lowers the desktop height at a low speed; and when the user moves the toggle 21 downward by the second travel distance (i.e., the lower trigger switch 322 is triggered), the desk 1 lowers the desktop height at a high speed.

Thus, compared to the fixed buttons used in electric height-adjustable desks of the prior art, the present disclosure determines the adjustment speed based on the travel distance through which the user moves the toggle 21, thereby effectively achieving adaptive speed control.

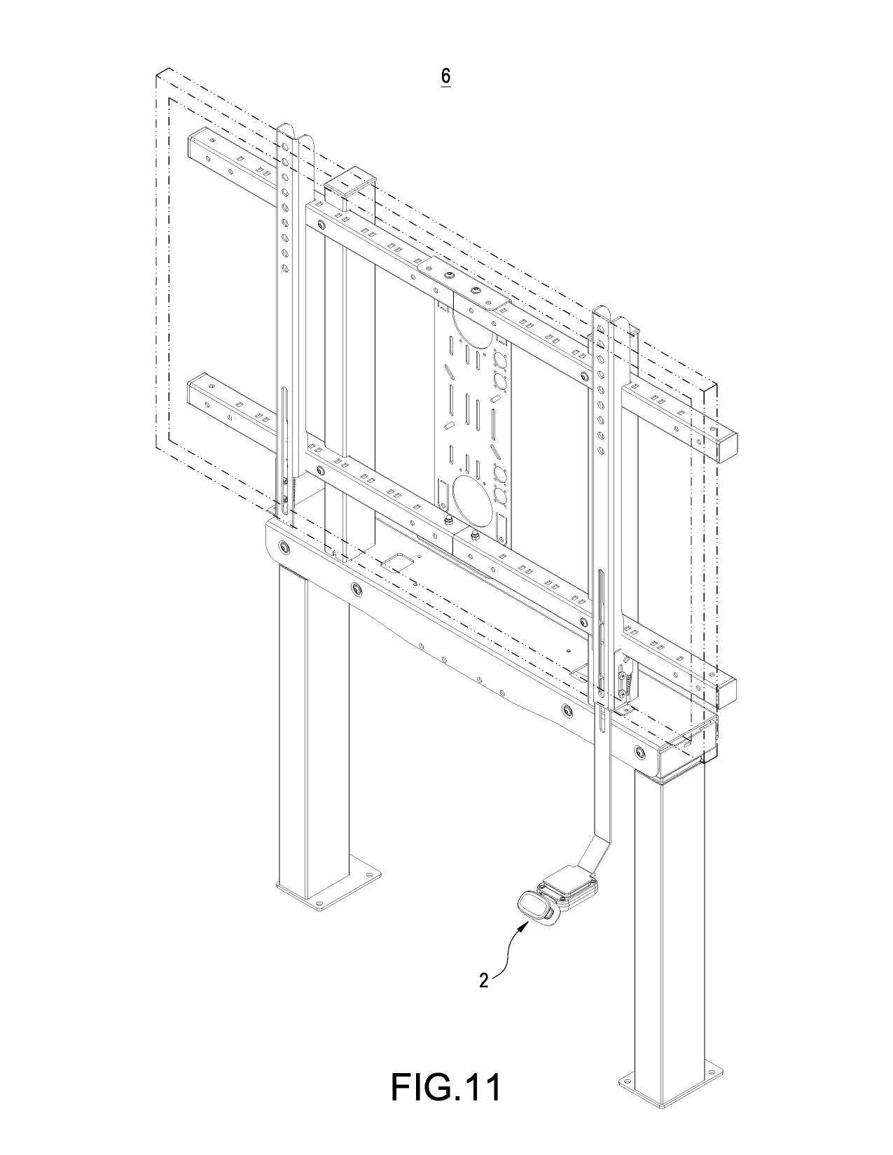

Referring to FIG. 11, a schematic diagram of an electric TV stand with the toggle control device is shown. As illustrated, the toggle control device 2 of the present disclosure may also be connected to an electric TV stand 6 to adjust its height. For example, when the user moves the toggle 21 of the toggle control device 2 upward by the first travel distance (i.e., the Hall sensor 31 approaches the first magnetic body 41), the electric TV stand 6 raises the stand height at a slow speed; when the user moves the toggle 21 upward by the second travel distance (i.e., the upper trigger switch 321 is triggered), the electric TV stand 6 raises the stand height at a high speed. Conversely, when the user moves the toggle 21 downward by the first travel distance (i.e., the Hall sensor 31 approaches the second magnetic body 42), the electric TV stand 6 lowers the stand height at a slow speed; and when the user moves the toggle 21 downward by the second travel distance (i.e., the lower trigger switch 322 is triggered), the electric TV stand 6 lowers the stand height at a high speed.

The embodiments shown in FIGS. 10 and 11 use the electric height-adjustable desk 1 and the electric TV stand 6 as illustrative examples. In other embodiments, the toggle control device 2 of the present disclosure may be applied to any type of electric furniture, allowing the user to freely determine the height adjustment speed based on the travel distance of the toggle 21.

In one embodiment, the electric furniture (e.g., the electric height-adjustable desk 1 and the electric TV stand 6) may include a controller, a receiving unit, a motor, and an adjustment unit (not shown). The receiving unit receives signals output by the Hall sensor 31, the upper trigger switch 321, and the lower trigger switch 322 from the toggle control device 2. The controller converts the signals into corresponding control commands. In another embodiment, the electric furniture and the toggle control device 2 share the same controller (not shown), which directly converts the signals into corresponding control commands. However, the above is merely one specific embodiment of the present disclosure and should not be construed as limiting.

The receiving unit may be implemented using various types of wired transmission units (e.g., transmission lines, connectors, or circuit pins) or wireless transmission units (e.g., Bluetooth modules, infrared modules, or Wi-Fi modules) to receive signals from the toggle control device 2. The controller may be implemented using a central processing unit (CPU), microcontroller unit (MCU), programmable logic controller (PLC), system on chip (SoC), or field-programmable gate array (FPGA), and is configured to generate control commands for controlling the electric furniture based on the received signals. The motor may be, for example, a direct current (DC) motor, linear motor, or stepper motor, and operates based on the control commands from the controller to drive the adjustment unit. As a result, components such as the desktop, desk legs, stand, or other parts of the electric furniture are raised or lowered in the direction and at the speed indicated by the control commands.

In one embodiment, the adjustment unit may be a transmission mechanism configured to connect the motor with the desktop, legs, stand, or other adjustable components of the electric furniture, thereby enabling the components to be raised or lowered by the rotational motion of the motor.

By using the toggle control device of the present disclosure, the user may freely determine the speed at which the electric furniture is raised or lowered based on the travel distance of the toggle movement, providing enhanced convenience.

What is claimed is:

1. A toggle control device for controlling height adjustment of electric furniture, the toggle control device comprising:
an upper housing;
a lower housing coupled to the upper housing to form a body, the body comprising an internal accommodation space;
a toggle comprising a carrier portion, a fixed portion disposed at one end of the carrier portion and configured to secure the toggle to the body, and a movable portion disposed at another end of the carrier portion, wherein the carrier portion and the fixed portion are located within the accommodation space, and the movable portion is exposed outside the body;
a Hall sensor disposed on the carrier portion;
a first magnetic body disposed on the upper housing; and
a second magnetic body disposed on the lower housing;
wherein, when the toggle is moved upward by a first travel distance and the Hall sensor is at a first upper critical position that is closer to the first magnetic body and farther from the second magnetic body, the Hall sensor generates a first signal corresponding to the first travel distance in response to a magnetic field of the first magnetic body;
wherein, when the toggle is moved downward by the first travel distance and the Hall sensor is at a first lower critical position that is closer to the second magnetic body and farther from the first magnetic body, the Hall sensor generates a second signal corresponding to the first travel distance in response to a magnetic field of the second magnetic body.

2. The toggle control device according to claim 1, wherein the first magnetic body and the second magnetic body have opposite magnetic polarities.

3. The toggle control device according to claim 1, further comprising at least one reset structure disposed on the carrier portion, the reset structure comprising a spring, an upper protruding column extending upward, and a lower protruding column extending downward, wherein, when the Hall sensor is at an initial position, the upper protruding column abuts an inner side of the upper housing, and the lower protruding column abuts an inner side of the lower housing.

4. The toggle control device according to claim 1, further comprising a circuit board disposed on the carrier portion, wherein the Hall sensor is electrically connected to the circuit board and is disposed on the carrier portion via the circuit board.

5. The toggle control device according to claim 4, further comprising:
an upper trigger switch electrically connected to a first surface of the circuit board facing the upper housing; and
a lower trigger switch electrically connected to a second surface of the circuit board facing the lower housing;
wherein the upper housing comprises an upper protrusion extending inward toward the circuit board, and the upper trigger switch is disposed on the circuit board at a position corresponding to a location of the upper protrusion on an inner side of the upper housing;
wherein the lower housing comprises a lower protrusion extending inward toward the circuit board, and the lower trigger switch is disposed on the circuit board at a position corresponding to a location of the lower protrusion on an inner side of the lower housing.

6. The toggle control device according to claim 5, wherein the upper trigger switch and the lower trigger switch are metal domes or snap domes.

7. The toggle control device according to claim 5, wherein when the toggle is moved upward by a second travel distance and the upper trigger switch is pressed and triggered by the upper protrusion, the upper trigger switch or a controller generates a third signal corresponding to the second travel distance;
when the toggle is moved downward by the second travel distance and the lower trigger switch is pressed and triggered by the lower protrusion, the lower trigger switch or the controller generates a fourth signal corresponding to the second travel distance;
wherein the second travel distance is greater than the first travel distance.

8. The toggle control device according to claim 7, wherein the electric furniture is an electric height-adjustable desk or an electric TV stand, wherein the first travel distance of moving upward the toggle indicates the electric furniture to raise its height at half speed; the first travel distance of moving downward the toggle indicates the electric furniture to lower its height at half speed; the second travel distance of moving upward the toggle indicates the electric furniture to raise its height at full speed; and the second travel distance of moving upward the toggle indicates the electric furniture to lower its height at full speed.

9. The toggle control device according to claim 4, wherein the toggle is an elongated structure, and the movable portion comprises a handle disposed on the carrier portion at an end away from the fixed portion, the handle being exposed outside the body.

10. The toggle control device according to claim 9, wherein a display panel is arranged inside the handle and electrically connected to the circuit board, the display panel being configured to display at least one of: a current travel distance of the toggle, a current height of the electric furniture connected to the toggle control device, or a current speed for height adjustment of the electric furniture connected to the toggle control device.
